(19) United States
(12) Patent Application Publication
(10) Pub. No.: US 2026/0068670 A1
(43) Pub. Date: Mar. 5, 2026

(54) SEMICONDUCTOR PACKAGE WITH ACTIVE THERMAL MANAGEMENT

(71) Applicant: Taiwan Semiconductor Manufacturing Company, LTD., Hsinchu (TW)

(72) Inventors: Tzu Jung Tien, Hsinchu (TW); Jen-Yuan Chang, Hsinchu (TW)

(21) Appl. No.: 18/823,985

(22) Filed: Sep. 4, 2024

(51) Int. Cl. H01L 23/38; H01L 23/00; H01L 23/043; H01L 23/31; H01L 23/367; H01L 23/538; H01L 25/16; H10N 10/10; H10N 19/00

(52) U.S. Cl. CPC H01L 23/38; H10N 10/10; H10N 19/00

(57) ABSTRACT

A semiconductor package includes a substrate with metal conductors, integrated circuit (IC) chips disposed on the substrate and electrically connected with the metal conductors of the substrate, thermoelectric cooler (TEC) chips thermally connected with the IC chips and having thermoelectric coolers configured to cool respective zones of the semiconductor package, temperature sensors arranged to measure temperatures of the respective zones of the semiconductor package, and control circuitry to operate the thermoelectric coolers to cool the respective zones based on the measured temperatures of the respective zones. The control may include determining whether a temperature-indicative signal satisfies a thermal management action criterion, and performing a thermal management action corresponding to the thermal management action criterion in response to a determination that the temperature-indicative signal satisfies the thermal management action criterion.

### BACKGROUND

The following relates to semiconductor packages and packaging arts and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B diagrammatically illustrate side sectional and top views, respectively, of a semiconductor package that includes integrated circuit (IC) chips and thermoelectric cooler (TEC) chips according to one embodiment.

FIG. 2 diagrammatically illustrates a side sectional view of a thermoelectric cooler of a TEC chip according to an embodiment.

FIG. 3 diagrammatically illustrates a side sectional view of a semiconductor package that includes IC chips and TEC chips, in which metal conductors of the substrate connect with the TEC chips to deliver operating power to the thermoelectric coolers of the TEC chips.

FIG. 4 diagrammatically illustrates a side sectional view of a semiconductor package that includes IC chips and TEC chips, and power leads distal from the substrate that are connected to deliver operating power to the thermoelectric coolers of the TEC chips.

FIG. 5 diagrammatically illustrate a side sectional view of a semiconductor package that includes IC chips and TEC chips according to another embodiment.

FIGS. 6 and 7 diagrammatically illustrate a side sectional view (FIG. 6) and a top view (FIG. 7) of a semiconductor package that includes an IC chip and a TEC chip according to another embodiment.

FIGS. 8 and 9 diagrammatically illustrate a side sectional view (FIG. 8) and a top view (FIG. 9) of a semiconductor package that includes an IC chip and a TEC chip according to another embodiment.

FIGS. 10 and 11 diagrammatically illustrate a side sectional view (FIG. 10) and a top view (FIG. 11) of a semiconductor package that includes a TEC chip cooling two IC chips according to another embodiment.

FIGS. 12 and 13 diagrammatically illustrate a side sectional view (FIG. 12) and a top view (FIG. 13) of a semiconductor package that includes two TEC chips cooling an IC chip according to another embodiment.

FIG. 14 diagrammatically illustrate a side sectional view of a semiconductor package that includes an IC chip and a TEC chip and an interposer according to another embodiment.

FIG. 15 diagrammatically illustrate a side sectional view of a semiconductor package that includes an IC chip and a TEC chip and an interposer according to another embodiment.

FIG. 16 diagrammatically illustrate a thermoelectric cooler of a TEC chip connected to output a thermoelectric signal indicative of a temperature of a semiconductor package.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package includes one or more integrated circuit (IC) chips fabricated on and/or in silicon or another semiconductor. The IC chips are disposed on a substrate. The IC chips may be directly attached to the substrate on which they are disposed, or may be arranged in a stack (e.g., with a lowermost IC chip directly attached to the substrate and one or more additional IC chips attached to the lowermost IC chip). In another arrangement, the one or more IC chips disposed on the substrate may be attached to an interposer, which in turn is attached to the substrate. The interposer may, for example, comprise a silicon wafer with through-vias. The substrate and/or the interposer (if included) may optionally include one or more redistribution layers (RDLs) to provide electrical routing of electrical signals and/or power to and/or from the one or more IC chips.

Thermal management is a challenge in semiconductor packages. Some such packages include IC chips that generate large quantities of heat. For example, an IC chip such as an advanced central processing unit (CPU) or graphical processing unit (GPU) for high performance computing (HPC) or an artificial intelligence (AI) application can output total chip power of around 400-600 watts or higher. A goal of some semiconductor package designs is to reduce the package footprint by close placement of multiple IC chips (some or all of which may be high-power IC chips), thus forming a concentrated high power heat source. Radiative and/or convective cooling can be provided by a heat sink, and/or by heat transfer through the substrate. The thermal load that can be conveyed by these heat transfer pathways may be limited, however. Additionally, these heat transfer pathways are uncontrolled, and so are designed to ensure adequate cooling for “worst-case” situations in which the semiconductor package is generating maximum heat.

Another thermal management challenge is that heating may be localized. For example, the semiconductor package may include a CPU or GPU that generate high amounts of heat, connected with other IC chips such as memory chips that generate much lower amounts of heat. Moreover, the heat generation may vary with time, e.g., the CPU or GPU may only generate a high heat load when it is performing computationally complex tasks such as AI model training; but at other times, may present a low heat load.

Disclosed herein are semiconductor packages with improved thermal management by inclusion of one or more thermoelectric cooler (TEC) chips hosting thermoelectric coolers that are thermally connected with the one or more IC chips of the semiconductor package. The TEC chip(s) can be advantageously placed at locations of high heat generation, and can advantageously be operated in concert with time intervals of high heat load generation. The thermoelectric cooler(s) of the TEC chip(s) actively draw heat from the package toward the air (or other ambient) surrounding the semiconductor package. In some embodiments, the semiconductor package further includes one or more temperature sensors to provide feedback control of the thermoelectric cooler(s) of the TEC chip(s). For example, a thermoelectric cooler may only be operated when its zone is at a temperature higher than a threshold temperature. In some embodiments, the thermoelectric cooler may serve as the temperature sensor, as its thermoelectric signal is temperature-dependent.

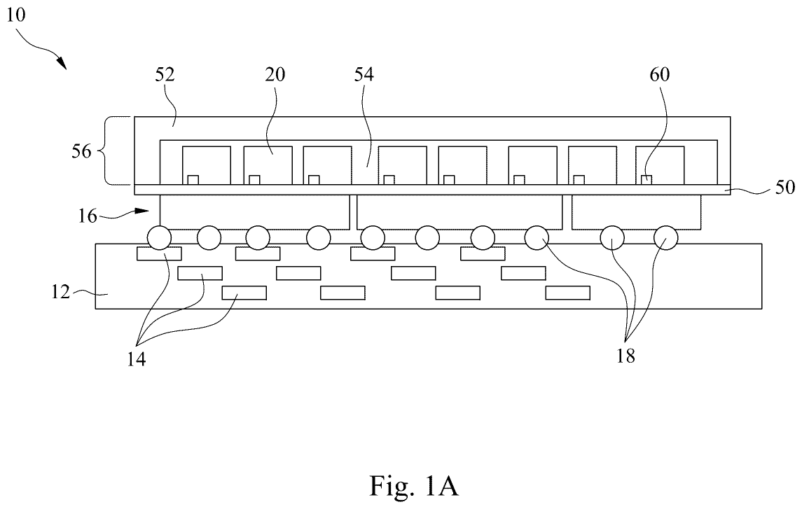

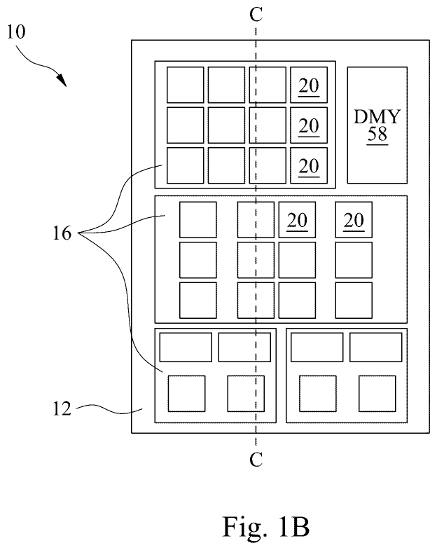

With reference now to FIGS. 1A and 1B, side sectional and top views, respectively, are diagrammatically illustrated of a semiconductor package 10. The sectional view of FIG. 1A is taken along cut C-C indicated in FIG. 1B. The semiconductor package 10 includes a substrate 12 with metal conductors 14. The substrate 12 can be of various types. In some embodiments, the substrate 12 may be a silicon wafer having through-silicon vias (TSVs) and a redistribution layer (RDL) on one or both sides providing the conductors 14 (details not shown). In other embodiments, the substrate 12 may comprise a resin material hosting a matrix of copper foil layers interconnected by vias forming the conductors 14 (details not shown). These are merely some nonlimiting illustrative examples of suitable embodiments of the substrate 12 with metal conductors 14.

One or more (illustrative three) integrated circuit (IC) chips 16 are disposed on the substrate 12, and are electrically connected with the metal conductors 14 by electrically conductive bonds 18 such as a microarray of bonding bumps, ball grid array (BGA), or so forth. An underfill material (not shown) such as an epoxy (by way of nonlimiting illustrative example) may optionally fills the spaces around the electrically conductive bonds 18 to provide improved structural robustness and/or contribute to thermal heat transfer from the IC chip or chips 16 to the substrate 12. The electrically conductive bonds 18 also provide electrical connections between the IC chip or chips 16 and the conductors 14 of the substrate 12. The IC chip or chips 16 of the embodiment of FIGS. 1A and 1B include three IC chips. By way of some nonlimiting illustrative examples, the IC chips may be: a system-on-integrated chip (SoIC), a monolithic die, a static random-access memory (SRAM) chip, or a combination thereof. More generally, the IC chip or chips 16 can be any type of integrated circuit chip. By way of some further nonlimiting examples, each IC chip 16 may be: a central processing unit (CPU); a graphical processing unit (GPU); a DRAM or other electronic memory chip; an IC chip carrying analog integrated circuitry, e.g. for analog radio frequency (RF) signal processing; various combinations thereof, and/or so forth. Again, there are merely some nonlimiting illustrative examples.

In the example of FIG. 1A, each IC chip 16 is bonded directly to the substrate 12 by the electrically conductive bonds 18. However, this is merely a nonlimiting illustrative example. Various arrangements of two or more IC chips can be employed, such as employing a silicon interposer with through-silicon vias (TSVs) and having the semiconductor dies mounted on the interposer which in turn is mounted on the substrate 12 (with TSVs of the interposer providing electrical connection between the semiconductor dies and the electrical conductors 14 of the substrate 12); a stack of two or more IC chips with only a bottommost chip directly bonded to the substrate (or interposer), and/or so forth. Moreover, in further embodiments it is contemplated for the one or more IC chips 16 to consist of a single IC chip, which may be directly attached to the substrate 12 or may have a silicon interposer disposed between the single IC chip and the substrate 12.

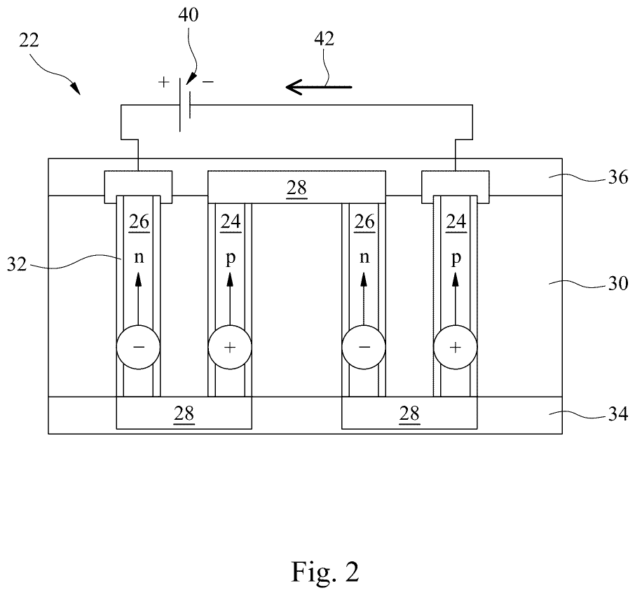

With continuing reference to FIGS. 1A and 1B and further reference to FIG. 2, the semiconductor package 10 of FIGS. 1A and 1B further includes at least one thermoelectric cooler (TEC) chip 20 comprising at least one thermoelectric cooler 22 (diagrammatically shown in FIG. 2). The TEC chip or chips 20 are thermally connected with the at least one IC chip 16.

With particular reference to FIG. 2, a side sectional view is shown of one thermoelectric cooler 22. The illustrative thermoelectric cooler 22 operates on the Peltier effect, and includes regions 24 which are doped p-type (i.e., p-type regions 24) and regions 26 which are doped n-type (i.e., n-type regions 26). The p-type regions 24 and n-type regions 26 are electrically interconnected in series by electrical conductors 28. The illustrative p-type and n-type regions 24 and 26 are embedded in a support 30, which may for example be silicon, resin, or so forth. If the support 30 is electrically conductive, then electrical insulation 32 may surround the p-type and n-type regions 24 and 26 to electrically isolate the p-type and n-type regions 24 and 26 from the support 30.

As seen in the example of FIG. 2, a first plate 34 and a second plate 36, which may be thermally conductive plates (e.g., thermally conductive but electrically insulating ceramic plates or the like) disposed at opposite ends of the p-type and n-type regions 24 and 26. A DC voltage source 40 applies a voltage across the series-interconnected p-type and n-type regions 24 and 26, producing an electric current 42 flowing through the series-interconnected p-type and n-type regions 24 and 26. As diagrammatically indicated in FIG. 2, this produces hole transport in the p-type regions 24 and electron transport in the n-type regions 26, with both the holes and electrons moving away from the first plate 34 and toward the second plate 36. The hole and electron transport thus operates by the Peltier effect to actively transport heat from the first plate 34 to the second plate 36. Thus, the thermoelectric cooler 22 operates to cool a mass in thermal contact with the first plate 34 by expelling heat from that first mass to the second plate 36. It is noted that for simplicity FIG. 2 illustrates only a few interconnected p-type and n-type regions 24 and 26. However, each thermoelectric cooler 22 may in general include an arbitrary number of interconnected p-type and n-type regions 24 and 26, which may optionally be arranged in a two-dimensional array or the like to provide cooling over a corresponding two-dimensional arca.

With returning reference to FIGS. 1A and 1B, the TEC chips 20 are disposed on the IC chips 16, and are thermally connected with the IC chips 16 by a thermal interface material 50 disposed between the TEC chips 20 and the IC chips 16. In the example of FIGS. 1A and 1B, the TEC chips 20 are arranged in a two-dimensional array, and a lid 52 is disposed over the TEC chips 20. A filler material 54 such as epoxy fills the lid 52. In this example the lid 52, the filler material 54, and the TEC chips 20 form a cooling plate 56 which is disposed on the IC chips 16. (Note that in FIG. 1B the lid 52 and filler 54 are omitted to reveal the layout of the TEC chips 20 and underlying IC chips 16). The lid 52 may, for example, be a metal (iron, nickel, chromium, tin, zinc, alloys thereof, et cetera), a carbon fiber material, glass, ceramic, or so forth. The thermal interface material 50 can be heat dissipation glue or another material providing good thermal conductivity and adhesion to the IC chips 16. (Alternatively, if the lid 52 is secured with the substate 12 by fasteners or the like, then a non-adhesive material can be used as the thermal interface material 50).

The example layout of FIG. 1B also shows an empty (DMY) socket 58 for an additional IC chip that is not included in the semiconductor package 10. Such an empty socket 58 (or multiple such sockets) can optionally be present if, for example, the substrate 12 is standardized and designed to support different chipsets for different models or tasks (e.g., the empty socket 58 could be used in some products to receive an additional SRAM chip to provide a model with greater memory capacity).

As best seen in the top view of FIG. 1B, the TEC chips 20 are distributed over the (illustrative) three IC chips 16 to provide targeted cooling to the IC chips 16. In some embodiments, the TEC chips 20 may operate continuously to provide continuous cooling of the IC chips 16 by the Peltier effect. However, the illustrative semiconductor package 10 includes temperature sensors 60 (or, more generally, at least one temperature sensor) to provide a temperature signal or signals for use in controlling the TEC chips 20. (Note, the temperature sensors 60 are not shown in the top view of FIG. 1B). For example, the TEC chips 20 disposed over a given IC chip 16 may be turned on only if temperature signal(s) from a temperature sensor or sensors 60 in a zone including that IC chip 16 indicate the temperature has risen about a threshold temperature. This advantageously enables the cooling provided by the TEC chips 20 to be targeted both spatially (e.g., only being turned on in a zone containing an IC chip whose temperature is too high) and temporally (e.g., only being turned on in that zone when the temperature is too high). The temperature sensor(s) 60 can be any suitable type of device that produces a temperature-dependent electrical output, such as thermocouples, thermistors, semiconductor-based temperature sensors, or so forth.

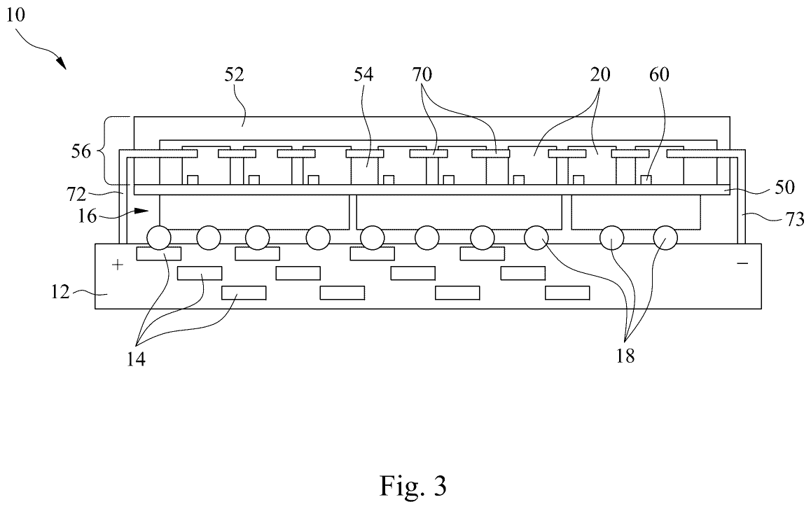

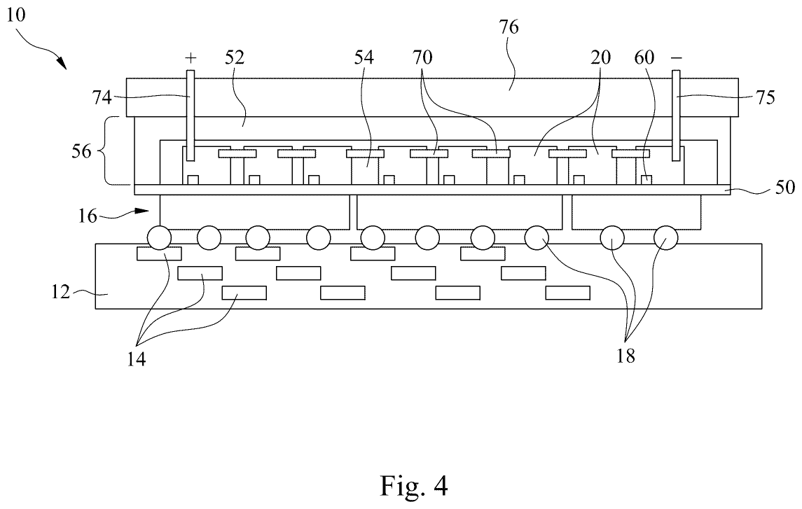

With reference to FIGS. 3 and 4, two nonlimiting illustrative configurations for electrical connections to the TEC chips 20 are shown. Each of FIGS. 3 and 4 illustrate a side sectional view of the semiconductor package 10 of FIG. 1, including the substrate 12 with metal conductors 14, the one or more IC chips 16 bonded to the substrate by the electrically conductive bonds 18, and the cooling plate 56 comprising the TEC chips 20 and lid 52 and filler material 54 and in thermal contact with the IC chips 16 by the thermal interface material 50. In both FIG. 3 and FIG. 4, the TEC chips 20 are electrically interconnected by electrical conductors 70.

In the example electrical connection configuration of FIG. 3, the metal conductors 14 of the substrate 12 connect with the at least one TEC chip 20 to deliver operating power to the at least one thermoelectric cooler of the at least one TEC chip 20. In FIG. 3, electrical leads 72 and 73 extend from the TEC chips 20 (themselves interconnected by electrical conductors 70) to the substrate 12, and an electrical voltage is applied across the leads 72 and 73 via the metal conductors 14 of the substrate 12. Although not shown, similar leads may connect the temperature sensor(s) 60 with the substrate 12 to read the temperature signal(s) therefrom via the metal conductors 14 of the substrate 12. In some embodiments, the electrical power for operating the TEC chip(s) 20 may be supplied externally from the semiconductor package 10.

In other embodiments, the electrical power for operating the TEC chip(s) 20 may be provided by the one or more IC chips 16 by way of the metal conductors 14 of the substrate 12. That is, the IC chip(s) 20 or a subset thereof (possible a single IC chip 20) includes integrated circuitry implementing a constant voltage source applying voltage across the electrical leads 72 and 73 of the cooling plate 56. This advantageously provides for the semiconductor package 10 to be self-contained insofar as a separate power supply for operating the TEC chip(s) 20 is not employed.

In the example electrical connection configuration of FIG. 4, the semiconductor package 10 further includes power leads 74 and 75 which are distal from the substrate 12, that are connected to deliver operating power to the at least one thermoelectric cooler of the at least one TEC chip 20. In the illustrative example, an optional epoxy or other molding material 76 is disposed over the cooling plate 56 to secure the connection of the leads 74 and 75 with the cooling plate 56.

It will be appreciated that the example electrical connection configurations of FIGS. 3 and 4 are nonlimiting illustrative examples, and that other approaches for connecting electrical power to the TEC chip(s) 20 of the semiconductor package 10 can be employed.

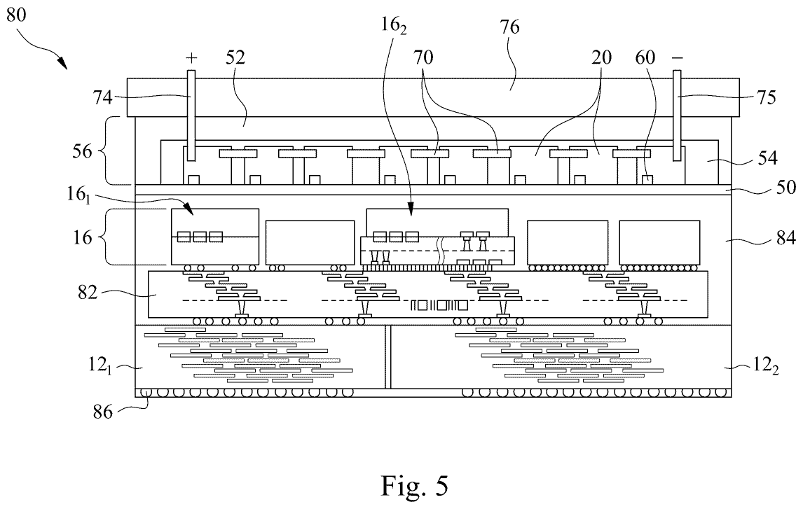

With reference to FIG. 5, another nonlimiting illustrative example of a semiconductor package 80 is shown, which has a similar configuration to that of FIGS. 1A, 1B, and 4 with some modifications to illustrate some nonlimiting examples of contemplated variability in the configuration of the semiconductor package. The semiconductor package 80 includes two substrates 12₁ and 12₂, and includes a larger number of IC chips 16 including an example of two examples of IC chip stacks 16₁ and 16₂ in which two IC chips are stacked one on the other, demonstrating a non-planar arrangement of the IC chips 16 in the example of FIG. 5. In one nonlimiting illustrative example, the IC chip stack 16₁ may include a top IC chip having an electrical integrated circuit (E-die) mounted on a bottom IC chip having a photonic integrated circuit (P-die), in which case the semiconductor package may be an optoelectronic semiconductor package. Additionally, the semiconductor package 80 includes an interposer 82 disposed between the IC chips 16 and the substrate 12, and a molding material 84 disposed around the IC chips 16 to provide structural robustness. The interposer 82 suitably includes redistribution layer(s) (RDL(s)), through-silicon vias (TSVs), or other electrical connections for transmitting electrical signals and/or power between the IC chips 16 and the substrate 12. The interposer 82 may be silicon, sapphire, or another suitable material.

The example of FIG. 5 includes the cooling plate 56 comprising the TEC chips 20 and lid 52 and filler material 54 in thermal contact with the IC chips 16 by the thermal interface material 50 (and, in this example, via the molding material 84). As in the example of FIG. 4, in the example of FIG. 5 the TEC chips 20 are electrically interconnected by electrical conductors 70, and further includes the power leads 74 and 75 which are distal from the substrate 12, and the optional epoxy or other molding material 76 disposed over the cooling plate 56 to secure the connection of the leads 74 and 75 with the cooling plate 56. It is contemplated to instead employ the electrical connections configuration of FIG. 3 in conjunction with the semiconductor package 80 of FIG. 5 (variant not shown).

FIG. 5 also illustrates a bottom of the substates 12₁ and 12₂ have electrically conductive bumps 86 via which (for example) the semiconductor package 80 may be mechanically and electrically connected to a printed circuit board (PCB, not shown) or other electronic system or device or component. The electrically conductive bumps 86 may be a BGA or the like. Although not shown in FIGS. 1A, 3, and 4, such a backside BGA or the like may likewise be included on the backside of the substrate 12 of the semiconductor package 10 shown in those embodiments.

In the examples described thus far, the TEC chip 20 are thermally connected with the IC chip 16 by an arrangement in which the TEC chips 20 are disposed on the IC chips 16 and thermally connected therewith by the thermal interface material 50 disposed between the TEC chips 20 and the IC chips 16. These embodiments advantageously maximize the footprint available for the IC chips 16, since the TEC chips 20 are disposed in a layer (or cooling plate 56) disposed on top of the IC chips 16.

In further embodiments described next, the TEC chip(s) 20 are disposed on the substrate 12 next to and/or interposed between the IC chip(s) 16. In these embodiments, the metal conductors 14 of the substrate 12 provide the thermal connection of the thermoelectric cooler(s) of the TEC chip(s) 20 with the IC chip(s) 16. These embodiments advantageously provide for connection of operational power to the TEC chip(s) 20 via the metal conductors 14 of the substrate 12, and the use of the metal conductors 14 for providing thermal connection to the IC chip 16 to be cooled also advantageously enables flexibility in placement of the TEC chips 20 respective to the IC chips 16.

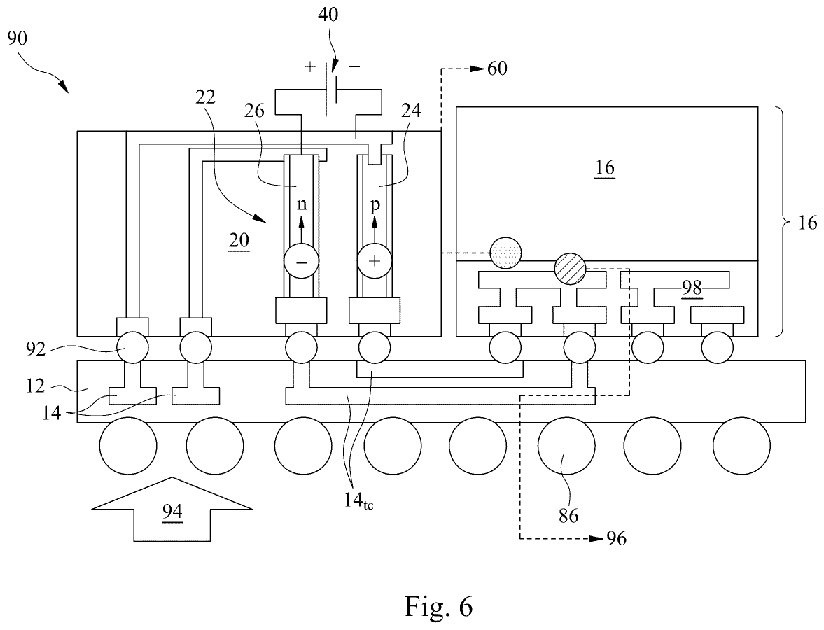

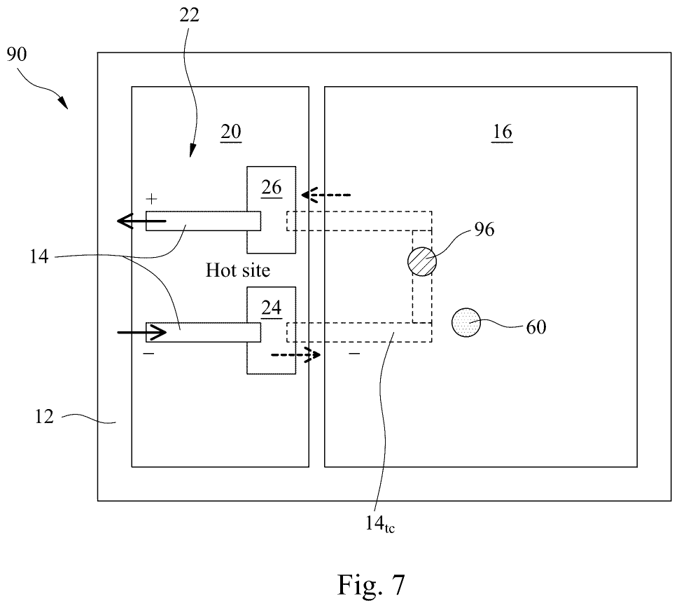

With reference to FIGS. 6 and 7, a side sectional view (FIG. 6) and a top view (FIG. 7) of a semiconductor package 90 is diagrammatically shown. As best seen in FIG. 6, the semiconductor package 90 includes a substate 12 with metal conductors 14 and electrically conductive bumps 86 via which the semiconductor package 90 may be mechanically and electrically connected to a PCB or the like, an IC chip 16, and a TEC chip 20 with a thermoelectric cooler 22. These components may be as previously described. In the embodiment of FIGS. 6 and 7, the TEC chip 20 is directly mounted to the substrate 12 (as seen in FIG. 6) by electrically conductive bumps 92 that also connect the TEC chip 20 to the metal conductors 14 of the substrate 12 to receive electrical power 94 for operating the thermoelectric cooler 22. The electrically conductive bumps 92 are also thermally conductive. As diagrammatically indicated in FIG. 6, the electrical power 94 is applied as a voltage source 40 to the p-type and n-type regions 24 and 26 of the thermoelectric cooler 22 of the TEC chip 20.

A portion of the metal conductors 14 of the substrate 12 also provide a thermal connection between the thermoelectric cooler 22 of the TEC chip 20 and the IC chip 16 to be cooled—these are indicated in FIG. 6 as metal conductors 14_{tc} which provide the thermal connection of the thermoelectric cooler 22 of the TEC chip 20 and the IC chip 16. As seen in the top view of FIG. 7, the metal conductors 14_{tc} conduct the operating current of the thermoelectric cooler 22, thus providing heat transfer from the IC chip 16 to the TEC chip 20 by both thermal conductivity of the metal conductors 14_{tc} and by electric carrier transfer. The metal conductors 14_{tc} can optionally form a serpentine or other tortuous path underneath the IC chip 16 to further promote thermal coupling.

In the illustrative example of FIGS. 6 and 7, a temperature sensor 60 is provided to measure a temperature signal indicative of a temperature of the IC chip 16, and additionally the IC chip 16 implements a switch 96, for example as a MOS transistor-based switch if the integrated circuitry of the IC chip 16 employs MOS technology. The switch 96 enables the operational current of the thermoelectric cooler 22 flowing through the metal conductors 14_{tc} to be turned off (e.g., by switching the MOS switch 96 to its nonconductive state) or to be turned on (e.g., by switching the MOS switch 96 to its conductive state). Thus, the IC chip 16 can implement feedback control of the thermoelectric cooler 22 of the TEC chip 20 by using the temperature measured by the temperature sensor 60 as the control input (e.g., feedback signal) and operating the switch 96 to turn the thermoelectric cooler 22 on when the measured temperature exceeds an off→on threshold, or off when the measured temperature falls below an on→off threshold. The temperature sensor 60 may be integral with the IC chip 16 (e.g., implemented in the integrated circuitry of the IC chip 16), or may be an external temperature sensor (e.g., a thermocouple) that is electrically connected with the IC chip 16 to be read by the IC chip 16.

With particular reference to FIG. 6, in this example the IC chip 16 includes a redistribution layer (RDL) 98 to facilitate routing of electrical signals and/or power between the IC chip 16 and the substrate 12. The RDL may, for example, comprise stack of patterned metallization layers embedded in intermetal dielectric (IMD) material, with vias interconnecting the patterned metal layers. It will be appreciated that any of the IC chips 16 herein may optionally include an RDL 98, even if not shown in a particular embodiment.

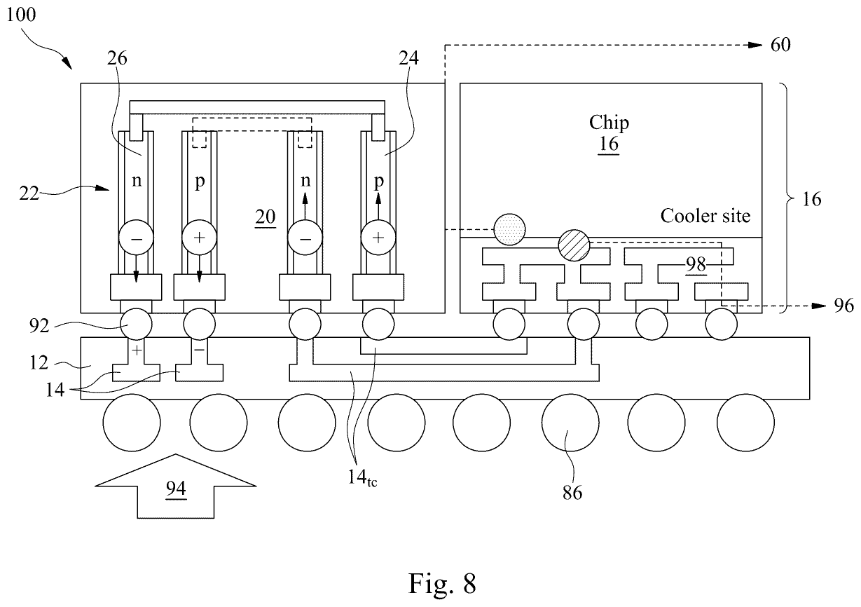

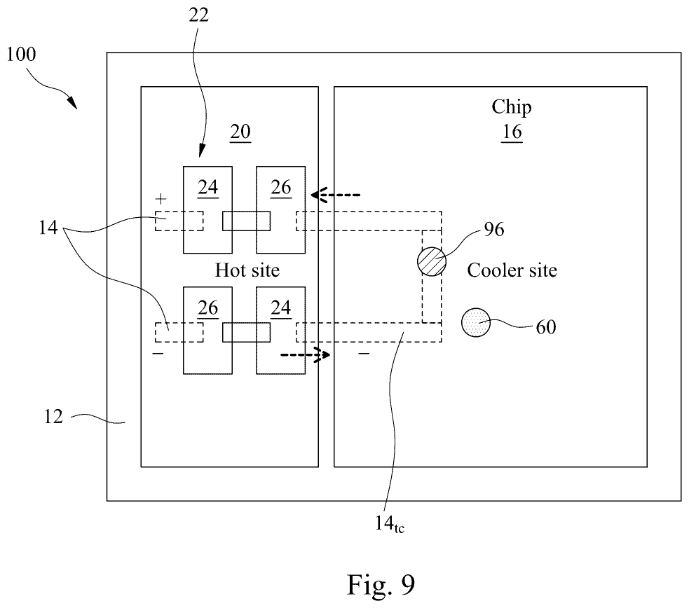

With reference to FIGS. 8 and 9, a side sectional view (FIG. 8) and a top view (FIG. 9) of a semiconductor package 100 is diagrammatically shown. This embodiment is similar to the embodiment of FIGS. 6 and 7 and corresponding components are labeled with corresponding reference numbers. The embodiment of FIGS. 8 and 9 differs from the embodiment of FIGS. 6 and 7 in that the thermoelectric cooler 22 of the TEC chip 20 in the embodiment of FIGS. 8 and 9 includes two illustrated p-type regions 24 and two illustrated n-type regions 26. This can be generalized—the thermoelectric cooler 22 of the TEC chip 20 can more generally include N p-type regions 24 and N n-type regions 26, where N may be one (as in FIGS. 6 and 7), two (as in FIGS. 8 and 9), three, four, five, six, seven, eight, or more. The N p-type regions 24 and N n-type regions 26 are electrically connected in series, and the thermal conduction metal conductors 14_{tc} of the substrate 12 can serve as a connection of this series interconnection circuit by running between a chosen p-type region 24 and a chosen n-type region 26. In a variant embodiment (not shown), there may be two (or more) independent thermoelectric coolers 22 implemented in a single TEC chip 20, with each thermoelectric cooler 22 having thermal conduction metal conductors 14_{tc} of the substrate 12 thermally connecting it with the IC chip 16 to be cooled.

In the examples of FIGS. 6-9, a single TEC chip 20 provides active cooling for a single IC chip 16.

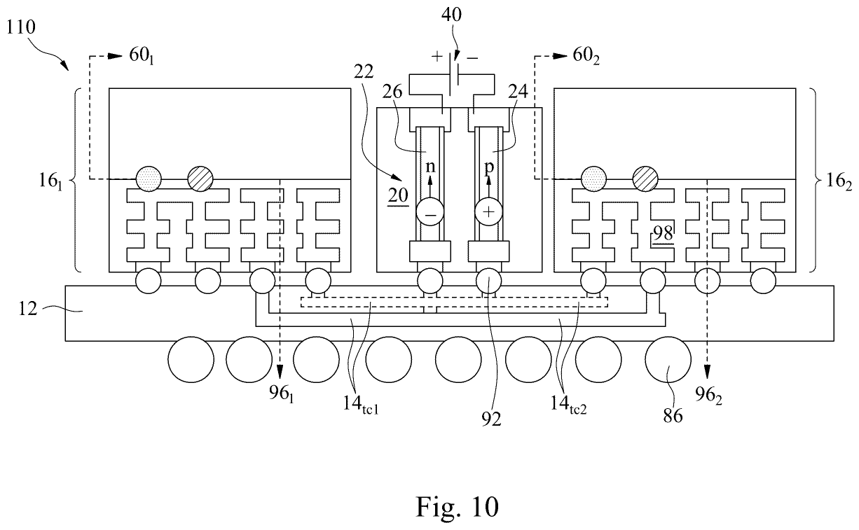

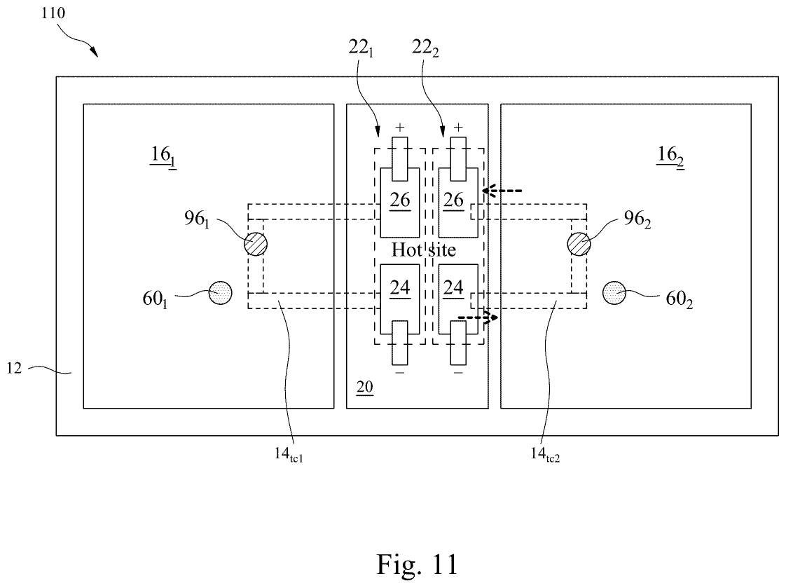

With reference to FIGS. 10 and 11, an example semiconductor package 110 is shown in which a single thermoelectric cooler 22 of a single TEC chip 20 provides cooling for two IC chips 16₁ and 16₂. In this example, the TEC chip 20 is interposed between the IC chip 16₁ and the IC chip 16₂ both of which are being cooled by the TEC chip 20. Thermal conduction metal conductors 14_{tc1} of the substrate 12 extend from the thermoelectric cooler 22 underneath the first IC chip 16₁, and thermal conduction metal conductors 14_{tc2} of the substrate 12 extend from the thermoelectric cooler 22 underneath the first IC chip 16₂. With particular reference to FIG. 11, in some embodiments the thermoelectric cooler 22 of the TEC chip 20 is implemented as two independent thermoelectric coolers 22₁ and 22₂, with the first thermoelectric cooler 22₁ being thermally connected with the first IC chip 16₁ by the thermal conduction metal conductors 14_{tc1} of the substrate 12 which extend from the first thermoelectric cooler 22₁ underneath the first IC chip 16₁; and similarly, the second thermoelectric cooler 22₂ being thermally connected with the second IC chip 16₂ by the thermal conduction metal conductors 14_{tc2} of the substrate 12 which extend from the second thermoelectric cooler 22₂ underneath the second IC chip 16₂. A first temperature sensor 60₁ monitors the temperature of the first IC chip 16₁, and a first MOS switch 96₁ implemented in the integrated circuitry of the first IC chip 16₁ switches the first thermoelectric cooler 22₁ on or off based on comparisons of the temperature measured by the first temperature sensor 60₁ with off→on and on→of thresholds. Likewise, a second temperature sensor 60₂ monitors the temperature of the second IC chip 16₂, and a second MOS switch 96₂ implemented in the integrated circuitry of the second IC chip 16₂ switches the second thermoelectric cooler 22₂ on or off based on comparisons of the temperature measured by the second temperature sensor 60₂ with the off→on and on→of thresholds. In this way, the single TEC chip 20 provides independent feedback-controlled active cooling of both the first IC chip 16₁ and the second IC chip 16₂.

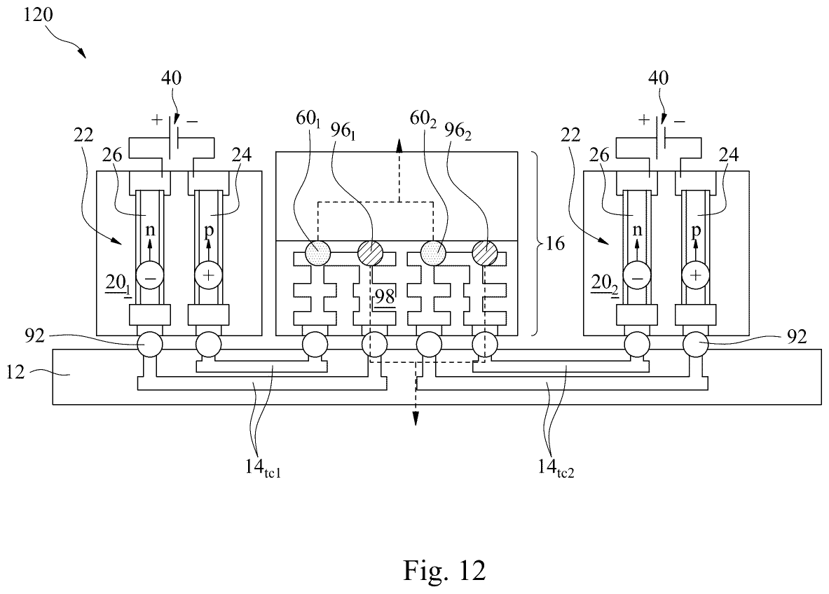

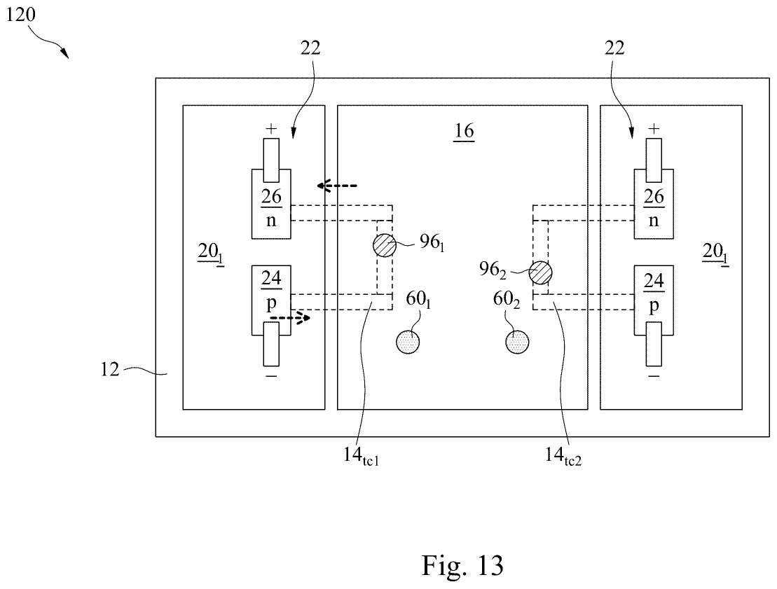

With reference to FIGS. 12 and 13, an example semiconductor package 120 is shown in which two TEC chips 20₁ and 20₂ provide cooling for a single IC chip 16. In this example, the single IC chip 16 is interposed between the two TEC chips 20₁ and 20₂, both of which provide active cooling to the IC chip 16. Thermal conduction metal conductors 14_{tc1} of the substrate 12 extend from the first TEC chip 20 underneath a first (e.g., lefthand) portion of the IC chip 16, and thermal conduction metal conductors 14_{tc2} of the substrate 12 extend from the second TEC chip 20 underneath a second (e.g., righthand) portion of the IC chip 16. A first temperature sensor 60₁ measures temperature of the first (e.g., lefthand) portion of the IC chip 16 and provides feedback for controlling a first MOS switch 96₁ that turns the thermoelectric cooler 22 of the first TEC chip 20₁ on or off; and likewise, a second temperature sensor 60₂ measures temperature of the second (e.g., righthand) portion of the IC chip 16 and provides feedback for controlling a second MOS switch 96₂ that turns the thermoelectric cooler 22 of the second TEC chip 20₂ on or off. This arrangement can be advantageous to provide independent active cooling of specific portions of a high-power IC chip such as a SoIC chip which may have nonuniform heat generation across the IC chip. While FIGS. 12 and 13 illustrate this being implemented for two chip portions (e.g., lefthand and righthand portions), it will be appreciated that this could be extended to provide independent active cooling of three or more portions of an IC chip. It will also be appreciated that in a variant embodiment (not shown), two thermoelectric coolers implemented in a single TEC chip (e.g., as shown in FIG. 11) could be used to provide the independent active cooling of different portions of a single IC chip.

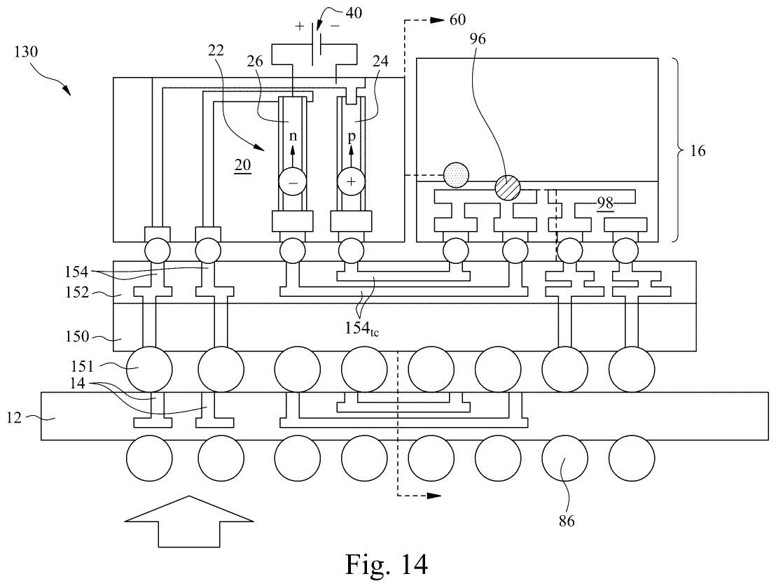

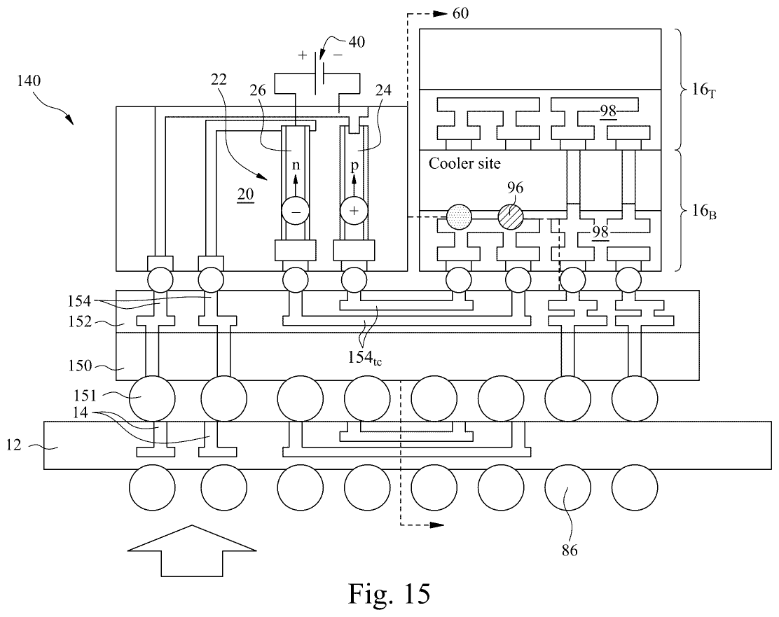

With reference now to FIGS. 14 and 15, still further example semiconductor packages 130 (FIGS. 14) and 140 (FIG. 15) are shown. These examples illustrate inclusion of an interposer 150 which is disposed between the at least one IC chip 16 and the substrate 12. The at least one IC chip 16 is disposed on the interposer 150 which in turn is disposed on the substrate 12 via electrically conductive bumps 151. In the illustrative examples of FIGS. 14 and 15, the TEC chip 20 is also disposed on the interposer 150. The interposer 150 includes an RDL 152 with metal conductors 154 delivering operational power to the TEC chip 20, and metal conductors 154_{tc} that thermally connect the at least one thermoelectric cooler 22 of the at least one TEC chip 20 with the at least one IC chip 16. Thus, the metal conductors 154_{tc} of the interposer 150 perform the analogous function as the metal conductors 14_{tc} of the substrate 12 in previous embodiments.

The semiconductor package 140 of FIG. 15 differs from the semiconductor package 130 of FIG. 14 in that the semiconductor package 130 of FIG. 14 includes a single IC chip 16; while the semiconductor package 140 of FIG. 15 includes two IC chips: a bottom IC chip 16_{B} on which a top IC chip 16_{T} is stacked. This illustrates that two (or, more generally, three or more) IC chips may be stacked in the semiconductor package.

In embodiments described thus far, temperature sensors 60 may be employed to measure a temperature signal to provide feedback based on which the at least one IC chip 16 may be configured (e.g., by suitable integrated circuitry such as op-amp-based comparators and the illustrative MOS switch 96) to operate the at least one thermoelectric cooler of the at least one TEC chip based on a temperature signal measured by the at least one temperature sensor 60.

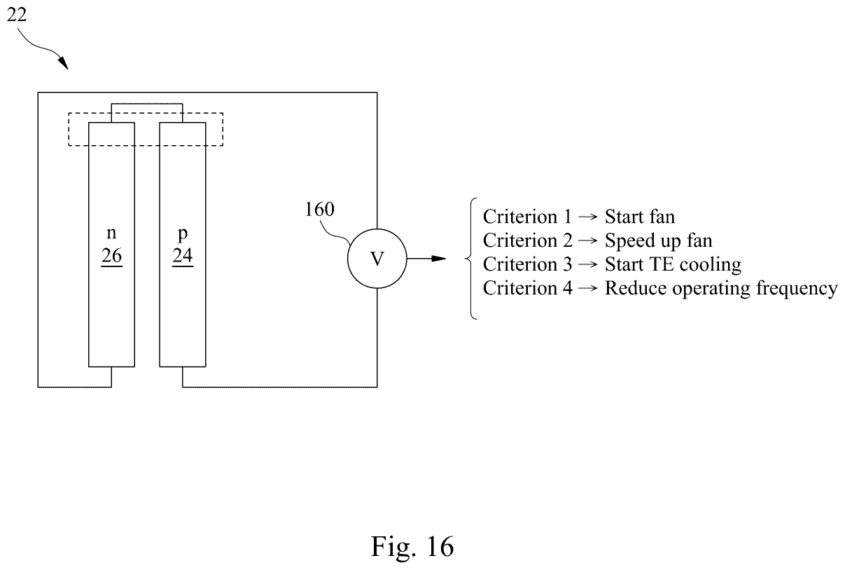

With reference to FIG. 16, in some alternative embodiments the thermoelectric cooler 22 can also serve as the temperature sensor. As diagrammatically shown in FIG. 16, a voltage difference 160 across the p-type region 24 and n-type region 26 is indicative of temperature. Hence, a temperature-indicative signal is measured (by the thermoelectric cooler 22 as shown in FIG. 16, or by a thermocouple or other dedicated temperature sensor 60 in other embodiments). The temperature-indicative signal is indicative of a temperature of the semiconductor package. Using integrated circuitry of the IC chip 16 of the semiconductor package, it is determined whether the temperature-indicative signal satisfies a thermal management action criterion. A thermal management action corresponding to the thermal management action criterion is performed in response to a determination that the temperature-indicative signal satisfies the thermal management action criterion. In the example of FIG. 16, the thermal management action criterion may include: Criterion 1; Criterion 2; Criterion 3; and Criterion 4. In some embodiments, each of Criterion 1, Criterion 2, Criterion 3, and Criterion 4 are successively higher temperature thresholds. In the nonlimiting illustrative example of FIG. 16, when Criterion 1 is satisfied a fan (not shown) configured to cool the semiconductor package is turned on. When Criterion 2 is satisfied (e.g., a higher temperature threshold than Criterion 1) the fan is speeded up (e.g., switched from low-speed to high-speed. When Criterion 3 is satisfied (e.g., a higher temperature threshold than Criterion 2) the thermoelectric cooler 22 is started. When Criterion 4 is satisfied (e.g., a higher temperature threshold than Criterion 3) an operating frequency of the IC chip 16 is reduced (to reduce power consumption of the IC chip). This is merely one nonlimiting illustrative example of an automated temperature management workflow.

In the following, some further embodiments are described.

In a nonlimiting illustrative embodiment, a semiconductor package includes: a substrate including metal conductors; at least one IC chip comprising an integrated circuit, the at least one IC chip disposed on the substrate and electrically connected with the metal conductors of the substrate; and at least one TEC chip comprising at least one thermoelectric cooler, the TEC chip being thermally connected with the at least one IC chip.

In a nonlimiting illustrative embodiment, a method of manufacturing a semiconductor package includes disposing at least one IC chip on a substrate, providing a thermal connection to the at least one IC chip, and disposing at least one thermoelectric cooler (TEC) in thermal contact with the at least one IC chip via the thermal connection.

In a nonlimiting illustrative embodiment, a method of manufacturing a semiconductor package includes disposing at least one IC chip on a substrate, disposing a thermal interface material on the at least one IC chip, and disposing at least one thermoelectric cooler (TEC) on the thermal interface material in thermal contact with the at least one IC chip via the thermal interface material.

In a nonlimiting illustrative embodiment, a method of manufacturing a semiconductor package includes disposing at least one IC chip on a substrate, providing metal conductors disposed in the substrate, and disposing at least one thermoelectric cooler (TEC) on the substrate thermally connected with the at least one IC via the metal conductors disposed in the substrate.

In a nonlimiting illustrative embodiment, a method of operating a semiconductor package is disclosed. The method includes: measuring a temperature-indicative signal that is indicative of a temperature of the semiconductor package; using an IC chip of the semiconductor package, determining whether the temperature-indicative signal satisfies a thermal management action criterion; and performing a thermal management action corresponding to the thermal management action criterion in response to a determination that the temperature-indicative signal satisfies the thermal management action criterion. In some such embodiments, the temperature-indicative signal may be a thermoelectric signal generated by a thermoelectric cooler of the semiconductor package. The thermal management action criterion may comprise the temperature-indicative signal indicating a temperature of the semiconductor package is higher than a threshold temperature, and the thermal management action may comprise operating the thermoelectric cooler to cool the semiconductor package.

In a nonlimiting illustrative embodiment, a semiconductor package includes: a substrate including metal conductors; IC chips disposed on the substrate and electrically connected with the metal conductors of the substrate; TEC chips thermally connected with the IC chips and comprising thermoelectric coolers arranged to cool respective zones of the semiconductor package; and temperature sensors arranged to measure temperatures of the respective zones of the semiconductor package; wherein the IC chips are configured to control the thermoelectric coolers.

In a nonlimiting illustrative embodiment, a semiconductor package includes a substrate with metal conductors, IC chips disposed on the substrate and electrically connected with the metal conductors of the substrate, TEC chips thermally connected with the IC chips and having thermoelectric coolers configured to cool respective zones of the semiconductor package, temperature sensors arranged to measure temperatures of the respective zones of the semiconductor package, and control circuitry to operate the thermoelectric coolers to cool the respective zones based on the measured temperatures of the respective zones. The control may include determining whether a temperature-indicative signal satisfies a thermal management action criterion, and performing a thermal management action corresponding to the thermal management action criterion in response to a determination that the temperature-indicative signal satisfies the thermal management action criterion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a substrate including metal conductors;
at least one integrated circuit (IC) chip comprising an integrated circuit, the at least one IC chip disposed on the substrate and electrically connected with the metal conductors of the substrate; and
at least one thermoelectric cooler (TEC) chip comprising at least one thermoelectric cooler, the TEC chip being thermally connected with the at least one IC chip.

2. The semiconductor package of claim 1, wherein the at least one TEC chip is disposed on the at least one IC chip, and is thermally connected with the at least one IC chip by a thermal interface material disposed between the at least one TEC chip and the at least one IC chip.

3. The semiconductor package of claim 2, wherein the metal conductors of the substrate connect with the at least one TEC chip to deliver operating power to the at least one thermoelectric cooler of the at least one TEC chip.

4. The semiconductor package of claim 2, further comprising power leads distal from the substrate that are connected to deliver operating power to the at least one thermoelectric cooler of the at least one TEC chip.

5. The semiconductor package of claim 2, further comprising:
a lid disposed over the at least one TEC chip; and
filler material filling the lid;
wherein the lid, the filler material, and the at least one TEC chip form a cooling plate which is disposed on the at least one IC chip.

6. The semiconductor package of claim 1, wherein the at least one TEC chip is disposed on the substrate next to and/or interposed between the at least one IC chip.

7. The semiconductor package of claim 6, wherein the metal conductors of the substrate thermally connect the at least one thermoelectric cooler of the at least one TEC chip with the at least one IC chip.

8. The semiconductor package of claim 7, wherein the metal conductors of the substrate which thermally connect the at least one thermoelectric cooler of the at least one TEC chip with the at least one IC chip conduct an operating electric current flowing through p-type regions and n-type regions of the at least one thermoelectric cooler of the at least one TEC chip.

9. The semiconductor package of claim 6, further comprising:
an interposer disposed between the at least one IC chip and the substrate;
wherein metal conductors of the interposer thermally connect the at least one thermoelectric cooler of the at least one TEC chip with the at least one IC chip.

10. The semiconductor package of claim 1, further comprising:
at least one temperature sensor;
wherein the at least one IC chip is configured to operate the at least one thermoelectric cooler of the at least one TEC chip based on a temperature signal measured by the at least one temperature sensor.

11. The semiconductor package of claim 1, wherein:
the at least one IC chip is configured to measure a thermoelectric signal generated by the at least one thermoelectric cooler of the at least one TEC chip and to control at least one package cooling operation based on the measured thermoelectric signal.

12. A method of manufacturing a semiconductor package, the method comprising:
disposing at least one integrated circuit (IC) chip on a substrate;
providing a thermal connection to the at least one IC chip; and
disposing at least one thermoelectric cooler (TEC) in thermal contact with the at least one IC chip via the thermal connection.

13. The method of claim 12, wherein:
the providing of the thermal connection to the at least one IC chip comprises disposing a thermal interface material on the at least one IC chip; and
the disposing of the at least one TEC in thermal contact with the at least one IC chip via the thermal connection comprises disposing the at least one TEC on the thermal interface material.

14. The method of claim 12, wherein:
the thermal connection to the at least one IC chip comprises metal conductors disposed in the substrate; and
the disposing of the at least one TEC in thermal contact with the at least one IC chip comprises disposing the at least one TEC on the substrate thermally connected with the at least one IC via the metal conductors disposed in the substrate.

15. A semiconductor package comprising:
a substrate including conductors;
integrated circuit (IC) chips disposed on the substrate and electrically connected with the conductors of the substrate;
thermoelectric cooler (TEC) chips thermally connected with the IC chips and comprising thermoelectric coolers configured to cool respective zones of the semiconductor package; and
temperature sensors arranged to measure temperatures of the respective zones of the semiconductor package;
wherein the IC chips are configured to control the thermoelectric coolers.

16. The semiconductor package of claim 15, wherein the TEC chips are disposed on the IC chips with a thermal interface material disposed between the TEC chips and the IC chips.

17. The semiconductor package of claim 16, further comprising:
a lid disposed over the TEC chips; and
epoxy filling the lid;
wherein the lid, the epoxy, and the TEC chips form a cooling plate which is disposed on the IC chips.

18. The semiconductor package of claim 15, wherein the TEC chips are disposed on the substrate next to and/or interposed between the IC chips.

19. The semiconductor package of claim 19, wherein the conductors of the substrate thermally connect the thermoelectric coolers of the TEC chips with the IC chips.

20. The semiconductor package of claim 19, further comprising:
an interposer on which the IC chips and TEC chips are disposed, the interposer being disposed on the substrate;
wherein conductors of the interposer thermally connect the thermoelectric coolers of the TEC chips with the IC chips.
